(19) United States
(12) Patent Application Publication
(10) Pub. No.: US 2007/0013012 A1
(43) Pub. Date: Jan. 18, 2007

(54) Etch-stop layer structure

(75) Inventors: Jhon-Jhy Liaw, Shin Chu (TW); Tze-Liang Lee, Hsinchin (TW)

Correspondence Address: Howard Chen;Preston Gates & Ellis LLP, Suite 1700, 55 Second Street, San Francisco, CA, 94105, US

(73) Assignee: Taiwan Semiconductor Manufacturing Co., Ltd.

(21) Appl. No.: 11/180,935

(22) Filed: Jul. 13, 2005

(51) Int. Cl. H01L 29/772; H01L 21/469

(52) U.S. Cl. 257/412; 438/791; 438/786; 438/624; 257/632

(57) ABSTRACT

A semiconductor structure that includes a first gate structure, second gate structure and a nitrogen-containing etch-stop layer. The first gate structure whose sidewalls are bounded by at least one first spacer is formed on a semiconductor substrate. The second gate structure whose sidewalls are bounded by at least one second spacer is formed on the semiconductor substrate, wherein the second gate structure is adjacent to the first gate structure. The nitrogen-containing etch-stop layer is formed over the first and second gate structures, having a thickness substantially the same over the semiconductor substrate, thereby improving a step coverage of a subsequent layer formed on the nitrogen-containing etch-stop layer between the first and second gate structures.

### BACKGROUND

The present invention relates generally to integrated circuits, and more particularly to an etch-stop layer that avoids the formation of the voids in semiconductor structures.

As integrated circuit (IC) structures are designed to be ever smaller, they are also placed closer together. This allows the IC chips to continue to become smaller. However, density and proximity of IC structures may raise certain manufacturing issues. For example, an etch-stop layer formed on two closely adjacent gate structures may cause difficulties in a subsequent formation of an inter-level dielectric layer thereon. An etch-stop layer is one that stops the progress of the etching of an overlying layer in some local areas so that the etching in other local areas can be completed. Such etch-stop layer is usually deposited on two closely adjacent gate structures before forming a contact structure therebetween. Conventionally, the thickness of the etch-stop layer varies substantially over the surfaces of the gate structures. This often causes formation of a void between the two adjacent gate structures in a subsequent inter-level dielectric layer deposition step.

Typically, the spaces between two adjacent gate structures have shapes of channels that are narrow and deep. After an etch-stop layer is formed on the gate structures, these channels do not always have simple shapes with strictly vertical, parallel walls. Since the thickness of the etch-stop layer varies, the so called overhead portions are often formed on the sides of the gate structures, thereby providing the channel with a neck portion. In a subsequent step of forming an inter-level dielectric layer, the dielectric material would first close the neck portion of the channel before it fills up its bottom portion. This may create a void in the inter-level dielectric layer at the bottom portion of the channel.

This void may not be harmful if it is never again opened. However, if succeeding pattern etches intrude into the void, it is a cavity that can retain contaminants. The void can also receive metal deposition if a conductive material penetrates into it. The trapped conductive material may not be easily removed from the unfortunately shaped void space by any conventional method. Then, or later, the trapped conductive material may function as an electrical shorting line between adjacent interconnect lines.

As such, desirable in the art of integrated circuit structure designs are designs and methods for avoiding the formation of voids in semiconductor structures caused by etch-stop layers of non-conformal thickness.

### SUMMARY

The present invention provides a semiconductor structure that includes a first gate structure, second gate structure and a nitrogen-containing etch-stop layer. The first gate structure whose sidewalls are bounded by at least one first spacer is formed on a semiconductor substrate. The second gate structure whose sidewalls are bounded by at least one second spacer is formed on the semiconductor substrate, wherein the second gate structure is adjacent to the first gate structure. The nitrogen-containing etch-stop layer is formed over the first and second gate structures, having a thickness substantially the same over the semiconductor substrate, thereby improving step coverage of a subsequent layer formed on the nitrogen-containing etch-stop layer between the first and second gate structures.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 illustrates a cross-sectional view of a semiconductor structure with a non-conformal etch-stop layer formed thereon.

FIG. 2 illustrates a cross-sectional view of a semiconductor structure with a conformal etch-stop layer formed thereon in accordance with one embodiment of the present invention.

FIG. 3 illustrates a cross-sectional view of the semiconductor structure having an inter-level dielectric layer formed on the etch-stop layer in accordance with the embodiment of the present invention.

### DESCRIPTION

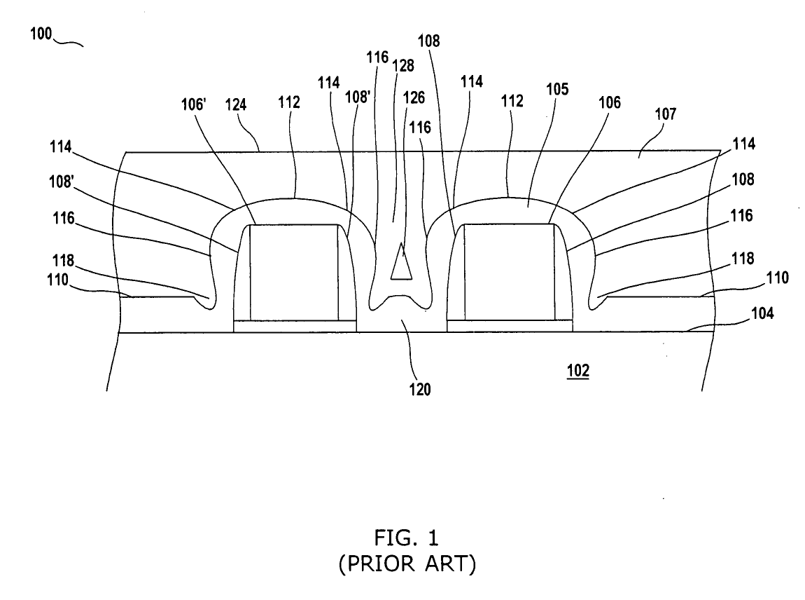

FIG. 1 illustrates a cross-sectional view of a semiconductor structure 100 with a conventional non-conformal etch-stop layer 105 deposited on a semiconductor substrate 102. A substrate 102, on which various structures are formed, has a surface 104. Two adjacent gate structures 106 and 106′ of MOS transistors are formed on the semiconductor substrate 102. Spacers 108 and 108′ are formed on the sidewalls of the gate structures 106 and 106′, respectively. The gate structures 106 and 106′, together with the spacers 108 and 108′, are coated with an etch-stop layer 105. The thickness of the etch-stop layer 105 varies substantially over the vertical surfaces and corners of the gate structures 106 and 106′. The etch-stop layer 105 has sections 110 covering the surface 104 of the semiconductor substrate 102 and sections 112 covering the top surfaces of the gate structures 106 and 106′. The etch-stop layer 105 also has sections 114, which have a severely diminished thickness covering the outside corners of the gate structures 106 and 106′. The etch-stop layer 105 also has sections 116, which are of a diminished thickness covering the nearly vertical surfaces of the spacers 108 and 108′. The etch-stop layer 105 also has sections 118, which are of a severely diminished thickness covering the inside corner where the sidewall spacers 108 and 108′ meet the surface 104. The etch-stop layer 105 also has a section 120 covering the bottom of the narrow vertical channel 128 between the spacers 108 and 108′ that are on the two neighboring and proximate gate structures 106 and 106′. The etch-stop layer 105 has therefore assumed a slightly “mushroomed” shape over the gate structures 106 and 106′. As illustrated in FIG. 1, the etch-stop layer 105 has diminished thickness at the bases of the mushroom shapes.

An interlayer dielectric (ILD) layer 107 is deposited to cover the entire etch-stop layer 105. The ILD is planarized, typically by a technique such as chemical-mechanical-polish (CMP), to produce a flat surface 124. However, the deposition of the ILD layer 107 in the narrow vertical channel 128, between the spacers 108 and 108′ that are on the two neighboring and proximate gate structures 106 and 106′, is non-conformal. Not only is this vertical channel 128 narrow and deep, but, because of the neighboring mushroom shaped etch-stop layer 105, it may also be wider at the bottom portion than at the upper portion. It is difficult to deliver enough ILD material into the bottom of the vertical channel 128 to completely fill it before the upper portion is covered by ILD material. This often causes formation of a void 126 in a narrow vertical channel 128 during the ILD deposition.

Among the contaminants that may eventually and permanently be trapped in the void 126 during succeeding processing is, metal from electrical interconnections for example. A further example of metal that may penetrate into the void 126 from an interconnection process can be seen in the contact tungsten plug deposition. It is difficult to remove all metal material from the narrow vertical channel 128. Any metal left in the channel can function as a shorting path between metal interconnect patterns. Also, thin sections of the etch-stop layer 105 can causes over-etching of its underlying material in an etching process subsequent to the formation of the ILD layer 107. These conditions can cause serious reliability problems.

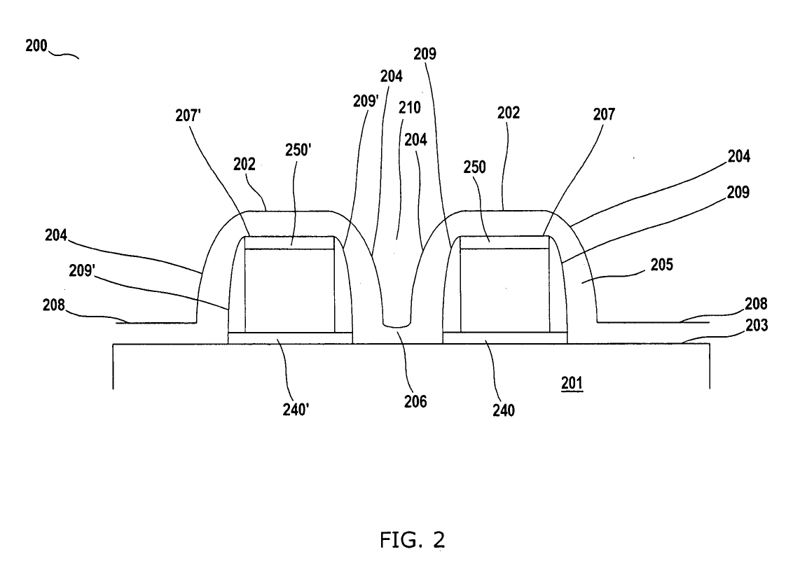

FIG. 2 illustrates a cross-sectional view of a semiconductor structure 200 having an etch-stop layer 205 of conformal thickness in accordance with one embodiment of the present invention. A substrate 201, on which various structures are formed, has a surface 203. Two adjacent gate structures 207 and 207′ of MOS transistors are formed on the semiconductor substrate 201. The gate structures 207 and 207′ are separated from the substrate 201 by gate dielectric layers 240 and 240′, respectively. In one example, the maximum thickness of the gate dielectric layers 240 and 240′ are about 26 angstroms. The gate structures 207 and 207′ have a space less than 200 nm. The gate structures 207 and 207′ may include metal or silicide layers 250 and 250′, respectively. The metal or silicide layers 250 and 250′ may be made of a material including refractory metals such as TiSi₂, CoSi₂, NiSi, Ptsi, W, WSi₂, TiN, TiW, TaN, or combinations thereof.

The gate structures 207 and 207′ also have sidewall spacers 209 and 209′, which are typically made of dielectric oxide of less than 350 angstroms. The sidewall spacers 209 and 209′ can be made of single or multiple layers made of materials including SiON, Si₃N₄, LPTEOS oxide, high temperature oxide (HTO), furnace oxide, Hf containing oxide, Ta containing oxide, Al containing oxide, high K dielectric (e.g. K>5), oxygen content dielectric, nitrogen content dielectric, or a combination thereof. The gate structures 207 and 207′, together with the sidewall spacers 209 and 209′, are coated with a conformal etch-stop layer 205, typically a Si₃N₄ or silicon oxynitride (SiON) layer, which is formed using a plasma-free low pressure chemical vapor deposition (LPCVD) process at a temperature below about 520 degrees Celsius. This process provides the etch-stop layer 205 with a thickness substantially the same over the gate structures 207 and 207′ and over the substrate 201. Other nitrogen containing etch-stop layers may be formed in other exemplary embodiments. Various high dielectric constant (K) dielectric layers may be formed in still other exemplary embodiments. The conformal etch-stop layer 205 formed by the LPCVD process has tensile stress no less than 1.1 Gpa. Since the deposition of the conformal layer is a non-plasma-enhanced process, plasma damage to the semiconductor structure 200 can be avoided.

To illustrate, the conformal etch-stop layer 205 is divided into various sections. Sections 202 of the conformal layer cover the top surfaces of the gate structures 207 and 207′. Sections 204 of the conformal etch-stop layer 205 cover the nearly vertical surfaces of the sidewall spacers 209 and 209′. A section 206 of the conformal etch-stop layer 205 covers the narrow portion of the surface 203 that lies between the sidewall spacers 209 and 209′ of the two neighboring and proximate gate structures 207 and 207′. Sections 208 of the conformal etch-stop layer 205 cover the broad exposed areas of the surface 203. In one exemplary embodiment, a plurality of layers may be formed, as above, to form the conformal etch-stop layer 205. A narrow vertical channel 210 is defined between the portions of the conformal etch-stop layers 205 on two adjacent sidewall spacers 209 and 209′ of the two neighboring and proximate gate structures 207 and 207′. Since the thickness of the etch-stop layer 205 is substantially the same over the gate structures 207 and 207′, the vertical channel 210 is narrower at the bottom portion than at upper portion. Thus, no mushroom shapes are produced. This avoids the formation of a void at the vertical channel 210 during a subsequent inter-level dielectric layer deposition process.

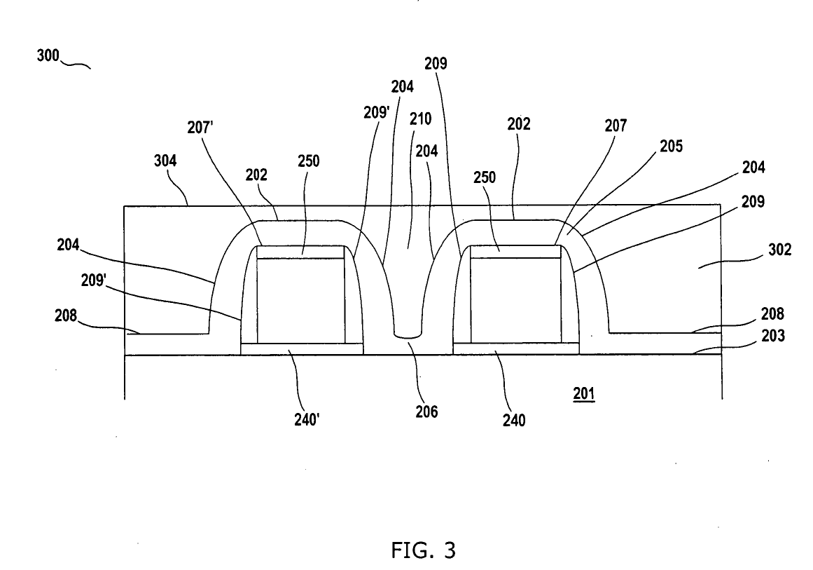

FIG. 3 illustrates a cross-sectional view of the semiconductor structure 300 having an ILD layer 302 formed on the etch-stop layer 205 in accordance with one embodiment of the present invention. An ILD layer 302 is deposited to cover all exposed IC structural surfaces. The ILD layer 302 is planarized, typically by a technique such as CMP, to produce a flat surface 304. The step coverage of the ILD layer 302 deposited at the vertical channel 210 is improved. In this embodiment, the step coverage of the ILD layer 302 at the vertical channel 210 is about 90%. Since the vertical channel 210 has a wider upper portion and a narrower bottom portion, the formation of a void in the ILD layer 302 at the vertical channel 210 can be avoided. Thus, the formation of tungsten-stringer, or any other metal short is also eliminated. With less hazard of producing voids and metal shorts, transistors and other components can be placed more closely together and greater integrated circuit density can be achieved. The size of memory cells can, therefore, be reduced.

After the formation of the ILD layer 302, a series steps of lithography, etching and deposition can be performed to form a contact structure at the channel 210 between two neighboring gate structures 207 and 207′. Because the conformal etch-stop layer 205 has uniform thickness, the etch results are more uniform. This means that a thinner etch-stop layer can be used. In one embodiment, the thickness of the etch-stop layer 205 can be less than 600 angstroms. This also means that there is a greater etch margin by using the conformal etch-stop layer 205.

This method and conformal etch-stop layer can be applied to dynamic random access memory (DRAM), static random access memory (SRAM), flash, non-volatile memory cells, and volatile memory cells. For example, the conformal etch-stop layer can be used in forming contacts in an SRAM cell that has a ratio of a longitudinal pitch and a transverse pitch in a range of about 1.7 to 8.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A semiconductor structure comprising:
a first gate structure whose sidewalls are bounded by at least one first spacer on a semiconductor substrate;
a second gate structure whose sidewalls are bounded by at least one second spacer on the semiconductor substrate, the second gate structure being adjacent to the first gate structure; and
a nitrogen-containing etch-stop layer formed over the first and second gate structures, having a thickness substantially the same over the semiconductor substrate, thereby improving a step coverage of a subsequent layer formed on the nitrogen-containing etch-stop layer between the first and second gate structures.

2. The semiconductor structure of claim 1 wherein the first and second gate structures have a space of no more than 200 nanometers.

3. The semiconductor structure of claim 1 wherein the thickness of the nitrogen-containing etch-stop layer is no more than 600 angstroms.

4. The semiconductor structure of claim 1 wherein the first and second spacers have a thickness of no more than 350 angstroms.

5. The semiconductor structure of claim 1 wherein the nitrogen-containing etch-stop layer has a tensile stress no less than 1.1 Gpa.

6. The semiconductor structure of claim 1 wherein the nitrogen-containing etch-stop layer is made of Si₃N₄ or SiON.

7. The semiconductor structure of claim 1 wherein the nitrogen-containing etch-stop layer has a dielectric constant no less than 5.

8. The semiconductor structure of claim 1 wherein each of the first and second gate structures further includes a metal-containing layer made of a refractory metal, metal silicide, TiSi₂, CoSi₂, NiSi, PtSi, W, WSi₂, TiN, TiW or TaN.

9. A method for forming an etch-stop layer used in formation of a contact structure between a first gate structure and an adjacent second gate structure on a semiconductor substrate, the method comprising:
forming an etch-stop layer over the first and second gate structures, having a thickness substantially the same over the semiconductor substrate, using a low pressure chemical vapor deposition process at a temperature less than 520 degrees Celsius; and
forming an inter-level dielectric layer on the etch-stop layer over the first and second gate structures, whereby a step coverage of the inter-level dielectric layer at an area between the first and second gate structures is improved.

10. The method of claim 9 wherein the step of forming an etch-stop layer is a substantially plasma-free operation.

11. The method of claim 9 wherein the etch-stop layer is made of a nitrogen-containing material made of Si₃N₄ or SiON.

12. The method of claim 13 wherein the etch-stop layer has a dielectric constant no less than 5.

13. The method of claim 9 wherein the thickness of the etch-stop layer is no more than 600 angstroms.

14. The method of claim 9 wherein the etch-stop layer has a tensile stress no less than 1.1 Gpa.

15. A semiconductor structure comprising:
a first gate structure whose sidewalls are bounded by at least one first spacer on a semiconductor substrate;
a second gate structure whose sidewalls are bounded by at least one second spacer on the semiconductor substrate, the second gate structure and the first gate structure having a proximity of no more than 200 nanometers; and
a nitrogen-containing etch-stop layer having a thickness of no more than 600 angstroms formed over the first and second gate structures, having a thickness substantially the same over the semiconductor substrate, thereby improving a step coverage of a subsequent layer formed on the nitrogen-containing etch-stop layer between the first and second gate structures.

16. The semiconductor structure of claim 15 wherein the first and second spacers have a thickness of no more than 350 angstroms.

17. The semiconductor structure of claim 15 wherein the nitrogen-containing etch-stop layer has a tensile stress no less than 1.1 Gpa.

18. The semiconductor structure of claim 15 wherein the nitrogen-containing etch-stop layer is made of Si₃N₄ or SiON.

19. The semiconductor structure of claim 15 wherein the nitrogen-containing etch-stop layer has a dielectric constant no less than 5.

20. The semiconductor structure of claim 15 wherein each of the first and second gate structures further includes a metal-containing layer made of a refractory metal, metal silicide, TiSi₂, CoSi₂, NiSi, Ptsi, W, WSi₂, TiN, TiW or TaN.
